(19) United States
(12) Patent Application Publication
(10) Pub. No.: US 2022/0246883 A1
(43) Pub. Date: Aug. 4, 2022

(54) FLEXIBLE DISPLAY PANEL, MANUFACTURING METHOD THEREOF, AND DISPLAY DEVICE

(71) Applicant: BOE Technology Group Co., Ltd., Beijing (CN)

(72) Inventors: Ziyu ZHANG, Beijing (CN); Fangxu CAO, Beijing (CN); Chengjie QIN, Beijing (CN)

(21) Appl. No.: 17/588,306

(22) Filed: Jan. 30, 2022

(30) Foreign Application Priority Data
Feb. 2, 2021 (CN) 202110145955.6

(51) Int. Cl. H01L 51/52; H01L 51/00; H01L 27/32; H01L 51/56

(52) U.S. Cl. CPC H01L 51/5253; H01L 51/0097; H01L 2227/323; H01L 51/56; H01L 27/3272; H01L 27/3246

(57) ABSTRACT

Provided are a flexible display panel, a manufacturing method thereof, and a display device. The flexible display panel includes: a flexible substrate including a first surface and a second surface opposite to each other and a through hole that penetrates the flexible substrate in a direction from the first surface to the second surface; an organic coating layer disposed on a hole wall of the through hole; and a thin film transistor layer, a pixel unit and a thin film encapsulation layer that are stacked on the first surface, wherein orthographic projections of the thin film transistor layer and the pixel unit on the second surface are disposed at a side of an orthographic projection of the through hole on the second surface, and the thin film encapsulation layer extends along a side of the organic coating layer distal from the hole wall. By providing the organic coating layer, a contact area of direct contact between the thin film encapsulation layer and a glass substrate at a shielding position is reduced, such that the difficulty in separating the flexible substrate from the glass substrate is reduced.

### CROSS-REFERENCE TO RELATED APPLICATION

This application claims priority to Chinese patent application No. 202110145955.6, filed on Feb. 2, 2021 and entitled “FLEXIBLE DISPLAY PANEL, MANUFACTURING METHOD THEREOF, AND DISPLAY DEVICE”, the entire content of which is incorporated herein by reference.

### TECHNICAL FIELD

The present disclosure relates to the field of display device technologies, and more particularly, relates to a flexible display panel, a manufacturing method thereof, and a display device.

### BACKGROUND

At present, to improve the bending performance of a flexible display panel, the flexible display panel is partially perforated, and the bending performance of the flexible display panel is improved through structural deformation.

In the related art, a flexible display panel including a flexible substrate and pixel units is provided. The pixel units are disposed on the flexible substrate, a side of the flexible substrate where the pixel units are disposed is provided with a through hole that penetrates the flexible substrate in a thickness direction, and the through hole is deformed in response to the flexible substrate being stretched, such that the flexible display panel achieves a larger amount of deformation than material limits.

### SUMMARY

Embodiments of the present disclosure provide a flexible display panel, a manufacturing method thereof, and a display device.

In one aspect of the embodiments of the present disclosure, a flexible display panel is provided. The flexible display panel includes:

a flexible substrate including a first surface and a second surface opposite to each other and a through hole that penetrates the flexible substrate in a direction from the first surface to the second surface;

an organic coating layer disposed on a hole wall of the through hole; and

a thin film transistor layer, a pixel unit, and a thin film encapsulation layer that are stacked on the first surface, wherein orthographic projections of the thin film transistor layer and the pixel unit on the second surface are disposed at a side of an orthographic projection of the through hole on the second surface, and the thin film encapsulation layer extends along a side of the organic coating layer distal from the hole wall.

Optionally, the hole wall is coated with the organic coating layer, the through hole includes a hole bottom proximal to the second surface, and the hole wall includes a bottom corner disposed at the hole bottom; and

the organic coating layer extends from the hole wall to the bottom corner, and covers apart of the hole bottom from the bottom corner.

Optionally, the flexible substrate is provided with a first shielding structure protruding towards an inside of the through hole relative to the hole wall; and

in the direction from the first surface to the second surface, an orthographic projection of a first end of the organic coating layer distal from the first surface on the second surface is disposed at a side, proximal to the center of the hole bottom, of an orthographic projection of a second end of the first shielding structure distal from the hole wall on the second surface.

Optionally, the flexible substrate is provided with a first shielding structure protruding towards an inside of the through hole relative to the hole wall; and

in the direction from the first surface to the second surface, an orthographic projection of a first end of the organic coating layer distal from the first surface on the second surface is overlapped with an orthographic projection of a second end of the first shielding structure distal from the hole wall on the second surface.

Optionally, the organic coating layer includes a resin-based organic material.

Optionally, the thin film encapsulation layer includes a first inorganic encapsulation layer, an organic encapsulation layer, and a second inorganic encapsulation layer that are stacked, wherein the first inorganic encapsulation layer and the second inorganic encapsulation layer are disposed at two sides of the organic encapsulation layer and the organic encapsulation layer is hermetically coated with the first inorganic encapsulation layer and the second inorganic encapsulation layer.

Optionally, the thin film encapsulation layer includes an inorganic encapsulation layer and an organic encapsulation layer that are stacked, wherein an outer side of the pixel unit and the hole wall is hermetically coated with the inorganic encapsulation layer, and a side of the inorganic encapsulation layer distal from the flexible substrate is coated with the organic encapsulation layer.

Optionally, the flexible substrate includes an organic isolation layer and an inorganic isolation layer that are stacked on the first surface, wherein the organic isolation layer and the inorganic isolation layer surround the through hole and are provided with an isolation groove, an opening direction of the isolation groove being a direction from the second surface to the first surface and the isolation groove extending around a periphery of the through hole.

Optionally, in a direction opposite to the opening direction, an area of an orthographic projection of the inorganic isolation layer on a bottom of the isolation groove is greater than or equal to an area of an orthographic projection of the organic isolation layer on the bottom of the isolation groove.

Optionally, the flexible display panel includes a planarization layer and a pixel definition layer that are stacked on the thin film transistor layer, wherein the planarization layer is provided with a first opening, and the pixel definition layer is provided with a second opening:

the pixel unit includes a first electrode and a second electrode, and an organic light-emitting layer disposed between the first electrode and the second electrode, wherein the first electrode is disposed on the planarization layer, is opposite to the second opening, and is connected to the thin film transistor layer through the first opening; and

the organic light-emitting layer and the second electrode are disposed at the second opening.

Optionally, the first electrode is an anode, the second electrode is a cathode, the organic light-emitting layer and the cathode are disconnected at a side wall of the isolation groove, and the thin film encapsulation layer is contiguous in the isolation groove.

Optionally, the organic isolation layer and the planarization layer or the pixel definition layer are film layers disposed in a same layer and made from a same material.

Optionally, the pixel definition layer is provided with a support column.

Optionally, the flexible substrate includes a first organic substrate, a first inorganic substrate, and a second organic substrate that are stacked; and

the organic coating layer includes a first sub-coating layer and a second sub-coating layer, wherein the first sub-coating layer covers a part of the hole wall corresponding to the first organic substrate, and the second sub-coating layer covers a part of the hole wall corresponding to the second organic substrate.

Optionally, an orthographic projection of the first inorganic substrate on the second surface is overlapped with an orthographic projection of the first sub-coating layer on the second surface and an orthographic projection of the second sub-coating layer on the second surface.

Optionally, the flexible display substrate further includes an inorganic insulation film layer and a planarization layer that are stacked on a side of the first organic substrate distal from the first inorganic substrate, wherein the pixel unit is disposed on the planarization layer; and

an orthogonal projection of the inorganic insulation film layer on the second surface is overlapped with an orthogonal projection of the first sub-coating layer on the second surface.

In another aspect of the present disclosure, a method for manufacturing a flexible display panel is provided. The method includes:

providing a flexible substrate, wherein the flexible substrate includes a first surface and a second surface opposite to each other and a through hole that penetrates the flexible substrate in a direction from the first surface to the second surface;

forming an organic coating layer on the flexible substrate, wherein the organic coating layer is formed on a hole wall of the through hole; and

forming, on the first surface, a thin film transistor layer, a pixel unit, and a thin film encapsulation layer that are stacked, wherein orthographic projections of the thin film transistor layer and the pixel unit on the second surface are disposed at a side of an orthographic projection of the through hole on the second surface, and the thin film encapsulation layer extends along a side of the organic coating layer distal from the hole wall.

Optionally, providing the flexible substrate includes:

forming a flexible back plate on a base substrate, wherein the flexible back plate includes a perforated region and a pixel region, and a thin film transistor layer, a planarization layer, a first electrode, and a pixel definition layer are stacked in the pixel region:

forming the through hole in the perforated region of the flexible back plate by etching, to process the flexible back plate into the flexible substrate;

forming the organic coating layer on the flexible substrate includes:

forming a support column and the organic coating layer on the pixel definition layer, wherein the support column is configured to support a mask plate for manufacturing an organic light-emitting layer;

evaporating the organic light-emitting layer and a second electrode above the first electrode; and

upon forming, on the first surface, the thin film transistor layer, the pixel unit, and the thin film encapsulation layer that are stacked, the method further includes:

separating the base substrate from the flexible substrate using a laser lift-off device.

Optionally, the organic coating layer is manufactured by liquid coating of a resin photoresist.

In yet another aspect of the present disclosure, a display device including a flexible display panel is provided. The flexible display panel includes:

a flexible substrate including a first surface and a second surface opposite to each other and having a through hole that penetrates the flexible substrate in a direction from the first surface to the second surface;

an organic coating layer disposed on a hole wall of the through hole; and

a thin film transistor layer, a pixel unit, and a thin film encapsulation layer that are stacked on the first surface, wherein orthographic projections of the thin film transistor layer and the pixel unit on the second surface are disposed at a side of an orthographic projection of the through hole on the second surface, and the thin film encapsulation layer extends along a side of the organic coating layer distal from the hole wall.

### BRIEF DESCRIPTION OF THE DRAWINGS

For clearer descriptions of the technical solutions in embodiments of the present disclosure, the following briefly introduces the accompanying drawings required for describing the embodiments or the prior art. Apparently, the accompanying drawings in the following description show merely some embodiments of the present disclosure, and those of ordinary skill in the art may still derive other drawings from these accompanying drawings without creative efforts.

FIG. 1 is a schematic structural diagram of a flexible display panel according to the related art,

FIG. 2 is a sectional view of the flexible display panel in FIG. 1 not separated from a glass substrate at D-D:

FIG. 3 is a front view of a flexible display panel according to an embodiment of the present disclosure;

FIG. 4 is a sectional view of D-D in FIG. 3;

FIG. 5 is a schematic structural diagram of the flexible display panel in FIG. 4 separated from a glass substrate:

FIG. 6 is a schematic structural diagram of another flexible display panel according to an embodiment of the present disclosure;

FIG. 7 is a schematic structural diagram of yet another flexible display panel according to an embodiment of the present disclosure;

FIG. 8 is a flow chart of a method for manufacturing a flexible display panel according to an embodiment of the present disclosure, and

FIG. 9 is a flow chart of another method for manufacturing a flexible display panel according to an embodiment of the present disclosure.

Reference numbers in the drawings are described as below:
A—pixel region; B—perforated region; C—isolation region; F1—shielding position; F2—hole wall; F3—first shielding structure; F4—bottom corner;
1—glass substrate; 2—flexible substrate; 21—first organic substrate; 22—second organic substrate; 3—thin film transistor layer; 31—thin film transistor; 4—planarization layer; 5—first electrode; 6—pixel definition layer; 7—thin film encapsulation layer; 71—first inorganic encapsulation layer; 72—organic encapsulation layer; 721—mask part; 73—second inorganic encapsulation layer; 74—third inorganic encapsulation layer; 8—second electrode; 9—organic light-emitting layer; 10—through hole; 101—hole bottom; 11—pixel unit; 111—first sub-pixel; 112—second sub-pixel; 113—third sub-pixel; 12—barrier layer; 13—support column; 14—isolation groove; 15—inorganic isolation layer; 16—organic isolation layer; 17—organic coating layer; 171—first sub-coating layer; 172—second sub-coating layer; 173—third sub-coating layer; 18—first inorganic substrate.

### DETAILED DESCRIPTION

A flexible display panel may be subjected to uniaxial folding and great-radius crimping operations, but due to limitations of structure and material strain limits, the flexible display panel may not be subjected to bidirectional stretching deformation or small-curvature folding and crimping operations. In view of this, the flexible display panel needs to be partially perforated to achieve bidirectional deformation and a larger amount of deformation by structural deformation.

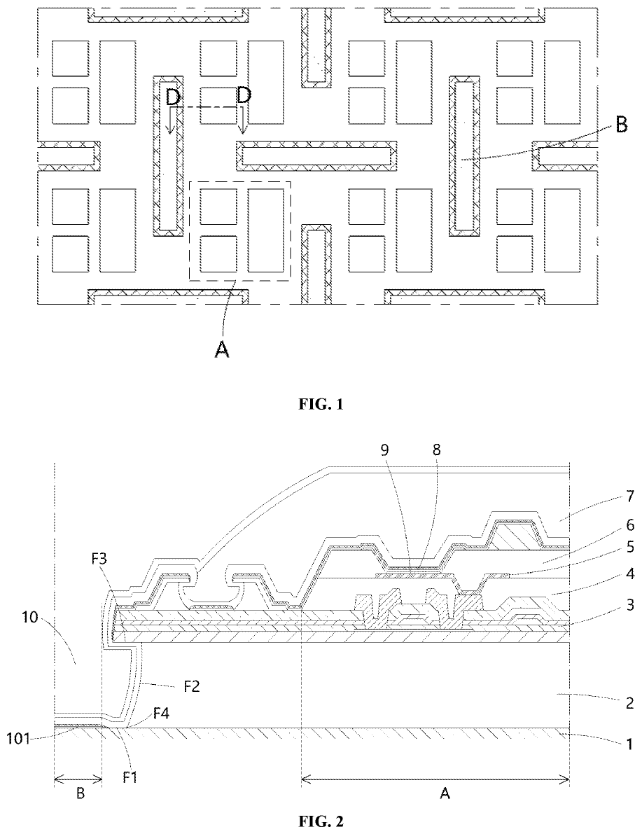

FIG. 1 is a schematic structural diagram of a flexible display panel according to the related art, and FIG. 2 is a sectional view of the flexible display panel in FIG. 1 not separated from a glass substrate at D-D. As shown in FIGS. 1 and 2, the flexible display panel includes a flexible substrate 2, a pixel unit, and a through hole 10. The flexible substrate 2 includes a pixel region A and a perforated region B. The pixel unit is disposed in the pixel region A of the flexible substrate 2, a plurality of pixel units form a pixel array on a side of the flexible substrate 2, and the pixel array defines an active area (AA) of the flexible display panel.

The through hole 10 that penetrates the flexible substrate 2 is formed in the perforated region B of the flexible substrate 2, and the through hole 10 is a micropore of which the size is equivalent to the size of the pixel unit 11. A region corresponding to the through hole 10 is the perforated region B disposed between the pixel regions A, and both of the perforated region B and the pixel region A are disposed in the active area of the flexible display panel.

The through hole 10 is prone to be deformed in response to the flexible substrate 2 being bent, and the deformation of the through hole 10 drives the pixel region A where the pixel unit is disposed to be stretched and rotated, thus achieving a larger amount of deformation than material limits.

The flexible display panel is manufactured by the following processes.

In S1, a glass substrate 1 is provided, wherein a back plate is manufactured on the glass substrate 1.

The process of manufacturing the back plate usually includes manufacturing the flexible substrate 2. It is known from the above descriptions that the flexible substrate 2 includes the pixel region A and the perforated region B. S1 further includes manufacturing a thin film transistor layer 3, a planarization layer 4, a first electrode 5, and a pixel definition layer 6 in the pixel region A.

In S2, the through hole 10 is formed in the perforated region B of the flexible substrate 2 by etching.

In S3, an organic light-emitting layer 9 and a second electrode 8 are evaporated on the pixel definition layer 6.

In S4, encapsulation is performed with a thin film encapsulation layer 7.

In S5, a material between a hole bottom 101 of the through hole 10 and the glass substrate 1 is removed by etching.

In S6, the glass substrate 1 is separated from the flexible substrate 2 using a laser lift-off device.

However, in practice, it has been found that the above processes have some defects.

In the case that the through hole 10 is etched in S2, a first shielding structure F3 is formed due to side etching (the side etching refers to etching of a side surface of a film material in the process of etching) of the flexible substrate 2 in the process of etching, the first shielding structure F3 vertically shields a region of the hole bottom 101 of the through hole 10 proximal to a bottom corner F4, and the position of this region is a shielding position F1, that is, in response to being viewed down from the top of the flexible substrate 2, the shielding position F1 is sheltered by the first shielding structure F3, and the shielding position F1 is not exposed upwards along the through hole 10. Therefore, in response to an organic material being evaporated on the glass substrate 1 at the hole bottom 101 of the through hole 10, the shielding position F1 cannot be evaporated, and thus a complete and contiguous organic film layer cannot be formed on the glass substrate 1 at the hole bottom 101 of the through hole 10.

In the case that the encapsulation is performed with the thin film based on this, the thin film encapsulation layer 7 is prone to be in direct contact with the glass substrate 1 at the shielding position F1 in response to extending to the hole bottom 101 along the hole wall F2 of the through hole 10. However, a direct contact between an inorganic encapsulation layer in the thin film encapsulation layer 7 and the glass substrate 1 adversely affects laser lift-off in S6, which results in difficulty in separation and affects the integrity of the separated flexible substrate 2.

In view of this, an embodiment of the present disclosure provides a method for manufacturing a flexible display panel. In the manufacturing process, the organic coating layer is formed by coating the hole wall F2 of the through hole 10 with an organic material before the thin film encapsulation process, and the thin film encapsulation layer 7 is disposed on a side of the organic coating layer distal from the hole wall F2. As the organic coating layer has a certain thickness, the thin film encapsulation layer 7 is farther away from the hole wall F2 than the thin film encapsulation layer 7 in the embodiment shown in FIGS. 1 and 2, thus reducing the area of direct contact between the thin film encapsulation layer 7 and the glass substrate 1 at the shielding position F1, and even avoiding direct contact between the thin film encapsulation layer 7 and the glass substrate 1. In this way, the difficulty in separating the flexible substrate 2 from the glass substrate 1 can be reduced, which makes it easier to separate the flexible substrate 2 from the glass substrate 1, achieves non-destructive separation, and further ensures the structural integrity of the flexible substrate 2.

To make the objects, technical solutions, and advantages of the embodiments of the present disclosure more clearly, the technical solutions in the embodiments of the present disclosure will be described clearly and completely with reference to the accompanying drawings in the embodiments of the present disclosure, and it is obvious that the described embodiments are some embodiments of the present disclosure, but not all embodiments. All other embodiments obtained by those skilled in the art based on the embodiments of the present disclosure without any creative effort fall within the protection scope of the present disclosure.

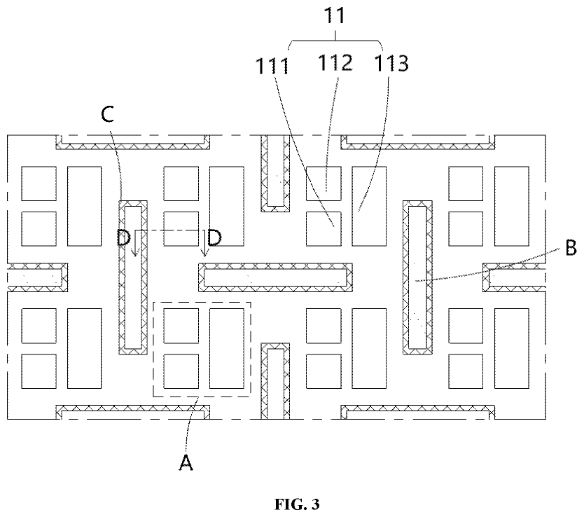

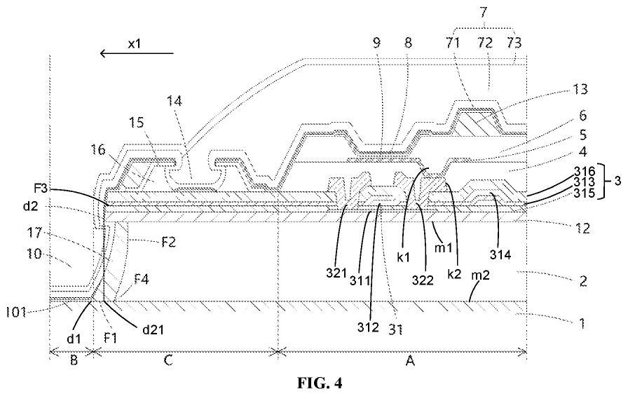

FIG. 3 is a front view of a flexible display panel according to an embodiment of the present disclosure, FIG. 4 is a sectional view of D-D in FIG. 3, and FIG. 5 is a schematic structural diagram of the flexible display panel in FIG. 4 separated from a glass substrate. As shown in FIGS. 3 to 5, the flexible display panel includes:

a flexible substrate 2 including a first surface m1 and a second surface m2 opposite to each other and a through hole 10 that penetrates the flexible substrate 2 in a direction from the first surface m1 to the second surface m2;

an organic coating layer 17 disposed on a hole wall of the through hole 10; and

a thin film transistor layer 3, a pixel unit 11, and a thin film encapsulation layer 7 that are stacked on the first surface m1, wherein orthographic projections of the thin film transistor layer 3 and the pixel unit 11 on the second surface m1 are disposed at a side of an orthographic projection of the through hole on the second surface, and the thin film encapsulation layer 3 extends along a side of the organic coating layer 17 distal from the hole wall F2.

In summary, m the flexible display panel according to the embodiment of the present disclosure, the organic coating layer is provided, and the thin film encapsulation layer is disposed at the side of the organic coating layer distal from the hole wall. As the organic coating layer has a certain thickness, the thin film encapsulation layer is farther away from the hole wall than the thin film encapsulation layer in the related art, thus reducing a contact area of direct contact between the thin film encapsulation layer and the glass substrate at the shielding position, and even avoiding direct contact between the thin film encapsulation layer and the glass substrate. In this way, the difficulty in separating the flexible substrate from the glass substrate can be reduced, which makes it easier to separate the flexible substrate from the glass substrate, achieves non-destructive separation, and further ensures the structural integrity of the flexible substrate.

In an exemplary embodiment, referring to FIGS. 3 to 5, the flexible display panel includes a flexible substrate 2 and a pixel unit 11. The flexible substrate 2 is of a flexible platy structure that is bendable and includes a first surface m1 and a second surface m2 opposite to each other. Taking the orientation shown in FIG. 4 as an example, the flexible substrate 2 is placed horizontally and laterally, and the first surface m1 is disposed above the second surface, that is, a direction from the first surface m1 to the second surface m2 is a vertical direction, which is also a thickness direction of the flexible substrate 2 and may also be called a direction perpendicular to the flexible substrate 2. It should be understood that the direction between the first surface m1 and the second surface m2 is parallel to a light-emitting direction of the flexible display panel.

The flexible substrate 2 may be made from polymer materials such as polyimide (PI), polycarbonate (PC), polyether sulfone (PES), polyethylene terephthalate (PET), polyethylene naphthalate (PEN), polyarylate (PAR), or glass fiber reinforced plastic (FRP). In this embodiment, the flexible substrate 2 may be made from PI.

The flexible substrate 2 is provided with a plurality of pixel units 11 on the first surface m1. The plurality of pixel units 11 are disposed on the flexible substrate 2 in an array to form a pixel array, and a region corresponding to the pixel array is an active area (AA) of the flexible display panel. The pixel units 11 may be organic light-emitting diodes (OLEDs), sub-millimeter light-emitting diodes (Mini LEDs), or micro light-emitting diodes (Micro-LEDs). In the present disclosure, the description is made by taking the pixel unit 11 as an OLED pixel unit as an example.

The pixel unit 11 includes a plurality of sub-pixels, each of which is a light-emitting device capable of emitting single color. For example, in the embodiment shown in FIG. 3, the pixel unit 11 includes a first sub-pixel 111, a second sub-pixel 112, and a third sub-pixel 113. The first sub-pixel 111 is a G sub-pixel capable of emitting green light, the second sub-pixel 112 is an R sub-pixel capable of emitting red light, and the third sub-pixel 113 is a B sub-pixel capable of emitting blue light. In the case that the flexible display panel displays, color display is realized by controlling the light emission of each sub-pixel.

The flexible substrate 2 is provided with a barrier layer 12, a thin film transistor layer 3, a planarization layer 4, a pixel unit 11, and a thin film encapsulation layer 7 on a side of the first surface m1. The barrier layer 12 may be an inorganic insulation film layer, may include inorganic materials such as oxides or nitrides, and may include multiple layers or a single layer containing inorganic materials. Due to material characteristics of the inorganic materials, the flexible substrate 2 is isolated from the structures on the flexible substrate 2, and penetration of foreign substances (such as moisture or air) under the flexible substrate 2 is reduced or blocked, and a planar surface can be provided.

The thin film transistor layer 3, disposed above the barrier layer 12, includes a thin film transistor 31 and a pixel circuit. The pixel circuit includes a data line and a scanning line intersecting with each other. The thin film transistor 31 may be of a top gate type, a bottom gate type, or a double gate type, which is not limited in the embodiment of the present disclosure.

The planarization layer 4 is disposed above the thin film transistor layer 3, covers the thin film transistor layer 3, and has a planar surface on a side distal from the thin film transistor layer 3.

The planar surface facilitates the fabrication and molding of the structures above. The planarization layer 4 is provided with a first opening k1 communicated with the thin film transistor layer 3.

A pixel definition layer 6 with a second opening k2 is disposed above the planarization layer 4.

The pixel unit 11 includes a first electrode 5, an intermediate layer, and a second electrode 8, and the intermediate layer is disposed between the first electrode 5 and the second electrode 8.

The first electrode 5 is disposed between the planarization layer 4 and the pixel definition layer 6, opposite to the second opening k2, and connected to the pixel circuit in the thin film transistor layer 3 through the first opening k1. The intermediate layer is disposed in the second opening k2, and the second electrode 8 is disposed on the other side of the intermediate layer opposite to the first electrode 5.

The intermediate layer includes an organic light-emitting layer 9, and may further include a common layer shared by all the sub-pixels in the pixel unit 11. The common layer may be at least one of a hole transport layer (HTL), a hole injection layer (HIL), an electron transport layer (ETL), and/or an electron injection layer (EIL).

In an exemplary embodiment, the thin film transistor 31 includes a channel material 311, a first gate 312, a second gate 314, a source 321, and a drain 322. The thin film transistor layer 3 may further include a first gate dielectric layer 315, a second gate dielectric layer 313, and an interlayer dielectric layer 316. The channel material 311, the first gate dielectric layer 315, the first gate electrode 312, the second gate dielectric layer 313, the second gate 314, the interlayer dielectric layer 316, the source 321, and the drain 322 are sequentially stacked on the barrier layer 12, and the source 321 and the drain 322 are respectively in contact with the channel material 311 through via holes.

In this embodiment, the first electrode 5 is an anode, the second electrode 8 is a cathode, and an organic light-emitting layer, the common laver, the cathode, and a dimming layer are sequentially disposed above the anode. The dimming layer is disposed at a side of the cathode distal from the intermediate layer, and is configured to correct and adjust light emitted by the organic light-emitting layer to improve the display effect. The organic light-emitting layer 9, the common layer, the cathode, and the dimming layer are manufactured using evaporation.

On the pixel definition layer 6 outside the second opening, a support column 13 is provided, and the support column 13 extends upwards in a thickness direction of the flexible substrate 2 to be distal from the top end of the pixel definition layer 6, to support a mask plate for evaporating the organic light-emitting layer 9.

The flexible substrate 2 includes the through hole 10 that penetrates the flexible substrate in the direction from the first surface m1 to the second surface m2. The flexible substrate 2 is provided with the through hole 10 in a region between the pixel units 11. The through hole 10 penetrates the flexible substrate 2 in a thickness direction of the flexible substrate 2. In the present disclosure, an end face of the through hole 10 proximal to the second surface m2 is a hole bottom 101 of the through hole 10, and a position of the hole wall F2 of the through hole 10 proximal to the second surface m2 is a bottom corner F4.

In the present disclosure, a region where the pixel unit 11 is disposed in the flexible substrate 2 is a pixel region A, and a region with the through hole 10 is a perforated region B. Both the perforated region B and the pixel region A are disposed in the active area of the flexible display panel, and the perforated region B is disposed between the pixel regions A in the active area.

The through hole 10 is prone to be deformed in response to the flexible substrate 2 being bent, and the deformation of the through hole 10 drives the pixel unit where the pixel area A is disposed to be stretched and rotated, thus achieving a larger amount of deformation than material limits.

The flexible display panel includes a thin film encapsulation layer 7, which covers the top of the pixel unit 11 to hermetically coat the pixel unit 11. The thin film encapsulation layer 7 extends to the hole bottom 101 along the hole wall F2 of the through hole 10. The thin film encapsulation layer 7 includes an organic encapsulation layer and an inorganic encapsulation layer that are alternately arranged. The inorganic encapsulation layer may be made from SiNₓ, SiCN, SiO₂, and the like, and the organic encapsulation layer may be made from acrylic polymer, silicon-based polymer, and the like. The inorganic encapsulation layer has excellent water-oxygen barrier properties, and the organic encapsulation layer can well absorb and disperse stress between layers, thereby protecting the dense inorganic encapsulation layer against cracks and improving the water-oxygen barrier property.

As shown in FIG. 4, in this embodiment, the thin film encapsulation layer 7 includes a first inorganic encapsulation layer 71, an organic encapsulation layer 72, and a second inorganic encapsulation layer 73. The first inorganic encapsulation layer 71 and the second inorganic encapsulation layer 73 are disposed at two sides of the organic encapsulation layer 72 and the organic encapsulation layer 72 is hermetically coated with the first inorganic encapsulation layer 71 and the second inorganic encapsulation layer 73 to give full play to the water-resistance of the inorganic encapsulation layer.

It is known from the foregoing descriptions that the through hole 10 is acquired by etching the flexible substrate 2. However, the first shielding structure F3 is formed by side etching of the through hole 10, and the first shielding structure F3 protrudes towards a central axis of the through hole 10 relative to the hole wall F2. In the direction from the first surface m1 to the second surface m2, the first shielding structure F3 of the through hole 10 shields the shielding position F1 of the hole bottom 101 of the through hole 10.

In addition, the hole wall F2 of the through hole 10 formed by etching is rough, resulting in poor coverage of a side wall of the through hole 10 with the thin film encapsulation layer 7. Thus, the reliability of encapsulation is reduced.

In the flexible display panel according to the embodiment of the present disclosure, the hole wall F2 and the shielding position F1 of the through hole 10 are coated with an organic material to form the organic coating layer 17. Here, an organic material from which the organic coating layer 17 is made may be selected according to actual processes, for example, a resin photoresist may be selected.

The organic coating layer 17 extends from the hole wall F2 to the bottom corner F4 proximal to the hole bottom 101 of the through hole 10, and covers a part of the hole bottom 101 of the through hole 10 from the bottom corner F4. Based on this structure, the coverage of the hole bottom 101 with the organic coating layer can be increased, the contact area of the thin film encapsulation layer and the hole bottom can be reduced, and the difficulty of separating the flexible display panel can be reduced.

The organic coating layer 17 extends along the hole wall F2 of the through hole 10, coats the rough wall surface of the hole wall F2 and has a smooth contact surface outside the hole wall F2. In the case that the thin film encapsulation layer 7 extends along the hole wall F2, the contact with the smooth contact surface of the organic coating layer 17 can ensure the reliability of encapsulation.

The organic coating layer 17 extends to the hole bottom 101 along the hole wall F2 of the through hole 10, and at the hole bottom 101, extends from the hole wall F2 along the first surface m1 towards the middle of the through hole 10, that is, at the bottom corner F4 of the through hole 10, extends along the first surface m1 towards the middle of the through hole 10. A first end d1 of the organic coating layer 17 distal from the hole wall F2 of the through hole 10 (that is, distal from the first surface m1) is aligned with the first shielding structure F3 or exceeds shielding of the first shielding structure F3 in a vertical direction of the flexible substrate 2. That is, an orthographic projection of the first end d1 on the first surface m1 (the position of the orthographic projection is overlapped with the position of the first end d1) is disposed at a side, proximal to the center of the hole bottom, of an orthographic projection d21 of a second end d2 of the first shielding structure F3 distal from the hole wall F2 on the first surface m1 (this structure is shown in FIG. 4), or, an orthographic projection of the first end d1 on the second surface m2 is overlapped with an orthographic projection d21 of the second end d2 on the second surface m2.

That is, the organic coating layer 17 can cover a part of the glass substrate 1 where the bottom hole 101 of the through hole 10 is sheltered by the first shielding structure F3, that is, cover the glass substrate 1 at the shielding position F1. The organic coating layer 17 works together with an evaporated organic film layer on the hole bottom 101 to form a complete and contiguous organic film layer corresponding to the hole bottom 101 of the through hole 10 on the glass substrate 1, to avoid direct contact between the thin film encapsulation layer 7 and the glass substrate and reduce the difficulty of separating the flexible substrate 2 from the glass substrate 1, which makes it easier to separate the flexible substrate 2 from the glass substrate 1, achieves non-destructive separation, and further ensures the structural integrity of the flexible substrate 2.

The above embodiment is described by taking the organic coating layer 17 covering the shielding position F1 and the hole wall F2 as an example. The organic coating layers disposed at the shielding position F1 and the hole wall F2 may be of the same or two different structures. However, the embodiment of the present disclosure is not limited thereto. For example, the organic coating layer 17 may be disposed only at the shielding position F1 in the case that only the problem of difficult separation is to be solved.

In addition, the organic coating layer 17 can cover the shielding position F1 or exceed a range of the shielding position F1, which is a preferred embodiment. However, in response to the organic coating layer 17 partially covering the shielding position F1, compared with the embodiment shown in FIGS. 1 and 2, the organic coating layer 17 can still reduce the difficulty in separating the flexible substrate 2 from the glass substrate 1, such that the flexible substrate 2 and the glass substrate 1 can be easily separated from each other, and the structural integrity of the flexible substrate 2 can be ensured.

For example, in a possible embodiment, the organic coating layer 17 may only be disposed on the hole wall F2, such that the problem of poor reliability in coating the etched hole wall F2 with the thin film encapsulation layer 7 can be solved. Moreover, as the organic coating layer has a certain thickness, the thin film encapsulation layer 7 is farther away from the hole wall F2 than the thin film encapsulation layer 7 in the embodiment shown in FIGS. 1 and 2, thus reducing the contact area of direct contact between the thin film encapsulation layer 7 and the glass substrate 1 at the shielding position F1, and even avoiding direct contact between the thin film encapsulation layer 7 and the glass substrate 1. In this way, the difficulty in separating the flexible substrate 2 from the glass substrate 1 can be reduced, which makes it easier to separate the flexible substrate 2 from the glass substrate 1, achieves non-destructive separation, and further ensures the structural integrity of the flexible substrate 2.

It should be noted that the organic coating layer 17 is partially removed in the process of manufacturing the flexible display panel. Therefore, in some embodiments, the organic coating layer 17 may not contain all the above structural features, the organic coating layer 17 may be disposed on the hole wall F2 of the through hole 10 and between the hole wall F2 and the thin film encapsulation layer 7.

To prevent water and oxygen from entering the organic light-emitting material from the through hole 10, the flexible display panel provided by the embodiment of the present disclosure is provided with an isolation groove 14 at the periphery of the through hole 10. As shown in FIGS. 3 and 5, a region at the periphery of the through hole 10 is an isolation region C. A side of the barrier layer 12 distal from the flexible substrate 2 is provided with an organic isolation layer 16 and an inorganic isolation layer 15 in the isolation region C. The organic isolation layer 16 and the inorganic isolation layer 15 are etched around the periphery of the through hole 10 to form the isolation grooves 14. An opening direction x2 of the isolation groove 14 faces upwards in a thickness direction of the flexible substrate 2, that is, a direction from the second surface m2 to the first surface m1. The organic isolation layer 16 may be disposed in the same layer and made from the same material as the planarization layer 4 or the pixel definition layer 6, that is, the organic isolation layer 16 may be manufactured in one patterning process with the planarization layer 4 or the pixel definition layer 6, thus reducing the process and the manufacturing difficulty.

The organic light-emitting layer 9 and the second electrode 8 are separated by the isolation groove 14, that is, disconnected by a side wall of the isolation groove 14 proximal to the organic light-emitting layer 9. The thin film encapsulation layer 7 is contiguous in the isolation groove 14.

The isolation groove 14 is provided, which can separate the organic light-emitting material and the through hole 10, such that a transmission path of water vapor is isolated, invasion of water and oxygen from the through hole 10 is blocked, and the display effect and the display reliability of the pixel unit 11 are ensured.

The isolation groove 14 is manufactured by etching. Similar to the through hole 10, a side etching structure is formed on a side wall. In this side etching structure, an area of an orthographic projection of the inorganic isolation layer 15 on the bottom of the isolation groove 14 is greater than or equal to an area of an orthographic projection of the organic isolation layer 16 on the bottom of the isolation groove 14 in a direction opposite to the opening direction of the isolation groove. In this way, an isolation effect of the inorganic isolation layer 15 can be ensured, and at the same time, the side etching structure can effectively prevent the organic encapsulation layer 72 from flowing into the through hole 10 during thin film encapsulation, such that the organic encapsulation layer 72 can be coated with the inorganic encapsulation layer.

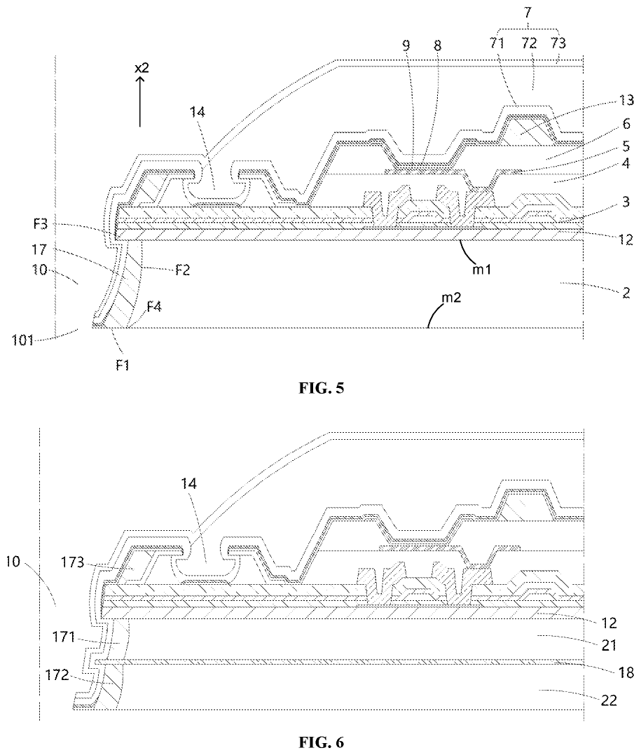

FIG. 6 is a schematic structural diagram of another flexible display panel according to an embodiment of the present disclosure. As shown in FIG. 6, this embodiment differs from the above embodiment in that the flexible substrate is of a double-layer structure, including a first organic substrate 21 and a second organic substrate 22, and a first inorganic substrate 18 disposed between the first organic substrate 21 and the second organic substrate 22. The first organic substrate 21 and the second organic substrate 22 may be made from polymer materials such as polyimide (PI), polycarbonate (PC), polyether sulfone (PES), polyethylene terephthalate (PET), polyethylene naphthalate (PEN), polyarylate (PAR), or glass fiber reinforced plastic (FRP). In this embodiment, both the first organic substrate 21 and the second organic substrate 22 are made from PI. The first inorganic substrate 18 may include inorganic materials, such as oxides or nitrides, and may also include multiple layers or a single layer containing inorganic materials, and due to the material characteristics of the inorganic materials, the first organic substrate 21 and the second organic substrate 22 are isolated from each other.

Taking the orientation shown in FIG. 6 as an example, the first organic substrate 21 is disposed above the first inorganic substrate 18, and the second organic substrate 22 is disposed below the first inorganic substrate 18. Corresponding to the double-layer structure, an organic coating layer includes a first sub-coating layer 171 and a second sub-coating layer 172, wherein the first sub-coating layer 171 covers a part of the hole wall F2 corresponding to the first organic substrate 21, and the second sub-coating layer 172 covers a part of the hole wall F2 corresponding to the second organic substrate 22. In a direction perpendicular to the flexible substrate, the first inorganic substrate 18 and an inorganic insulation film layer (a barrier layer 12) are overlapped with the first sub-coating layer and the second sub-coating layer, that is, an orthogonal projection of the first inorganic substrate 18 on a second surface m2 is overlapped with an orthogonal projection of the first sub-coating layer 171 on the second surface m2 and an orthogonal projection of the second sub-coating layer 172 on the second surface m2.

The inorganic insulation film layer is further provided with a third coating laver 173, which is disposed on a side of an isolation groove 14 proximal to the through hole 10. The third coating layer 173 is an invalid structure left during the process of manufacturing the organic coating layer 17.

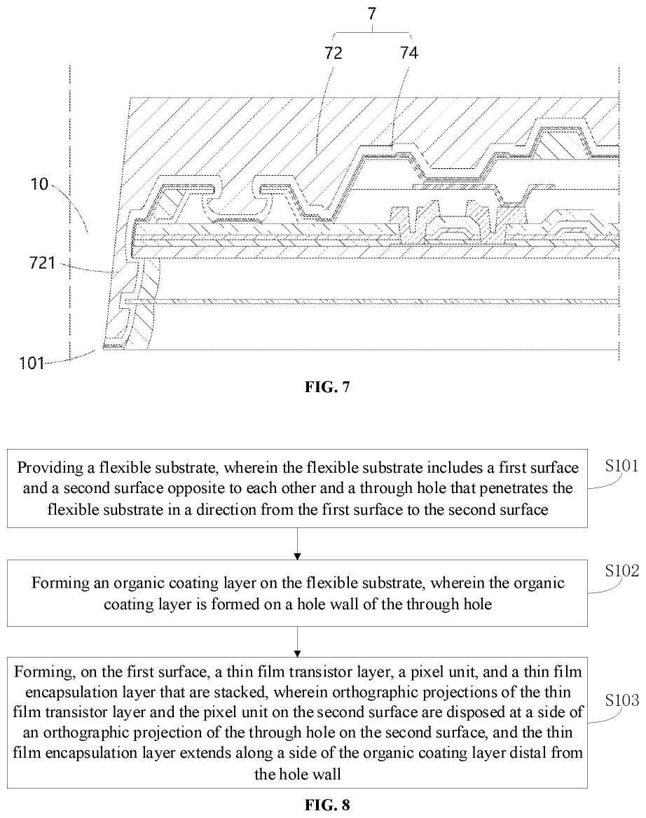

FIG. 7 is a schematic structural diagram of yet another flexible display panel according to an embodiment of the present disclosure. As shown in FIG. 7, the flexible display panel in this embodiment differs from the flexible display panel in FIG. 6 in a thin film encapsulation layer 7. In this embodiment, the thin film encapsulation layer 7 includes an organic encapsulation layer 72 and a third inorganic encapsulation layer 74. The organic encapsulation layer 72 is disposed above the third inorganic encapsulation layer 74, and the third inorganic encapsulation layer 74 mainly plays the role of blocking water and isolating the organic layer. An outer side of the organic encapsulation layer 72 has an outer side surface parallel to a first surface m1, such that the organic encapsulation layer plays the role of planarizing a surface and coating foreign matters.

Further, the organic encapsulation layer 74 has a mask part 721 disposed in the through hole, and the mask part 721 is a mask structure for etching the material of the hole bottom 101 of the through hole 10.

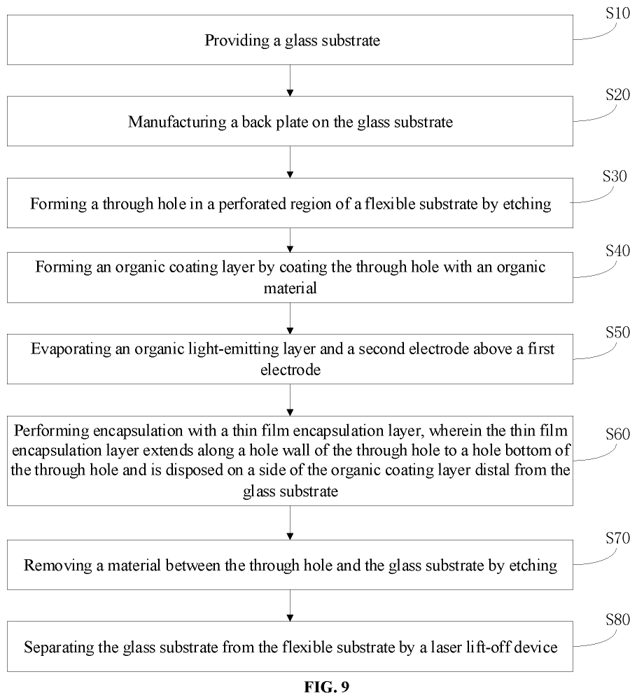

As shown in FIG. 8, which is a flow chart of a method for manufacturing a flexible display panel according to an embodiment of the present disclosure, the method includes the following processes.

In S101, a flexible substrate is provided, wherein the flexible substrate includes a first surface and a second surface opposite to each other and a through hole that penetrates the flexible substrate in a direction from the first surface to the second surface.

In S102, an organic coating layer is formed on the flexible substrate, wherein the organic coating layer is formed on a hole wall of the through hole.

In S103, on the first surface, a thin film transistor layer, a pixel unit, and a thin film encapsulation layer are stacked is formed, wherein orthographic projections of the thin film transistor layer and the pixel unit on the second surface are disposed at a side of an orthographic projection of the through hole on the second surface, and the thin film encapsulation layer extends along a side of the organic coating layer distal from the hole wall.

In summary, in the method for manufacturing the flexible display panel according to the embodiment of the present disclosure, the organic coating layer is formed on the hole wall of the through hole, and the thin film encapsulation layer is disposed on the side of the organic coating layer distal from the hole wall. As the organic coating layer has a certain thickness, the thin film encapsulation layer is farther away from the hole wall than the thin film encapsulation layer in the related art, thus reducing a contact area of direct contact between the thin film encapsulation layer and a glass substrate at a shielding position, and even avoiding direct contact between the thin film encapsulation layer and the glass substrate. In this way, the difficulty in separating the flexible substrate from the glass substrate can be reduced, which makes it easier to separate the flexible substrate from the glass substrate, achieves non-destructive separation, and further ensures the structural integrity of the flexible substrate.

The above S101 includes:

forming a flexible back plate on a base substrate, wherein the flexible back plate includes a perforated region and a pixel region, and a thin film transistor layer, a planarization layer, a first electrode, and a pixel definition layer are stacked in the pixel region; and

forming a through hole in the perforated region of the flexible back plate by etching, to process the flexible back plate into the flexible substrate.

The above S102 includes:

forming a support column and the organic coating layer on the pixel definition layer, wherein the support column is configured to support a mask plate for manufacturing an organic light-emitting layer; and

evaporating the organic light-emitting layer and a second electrode above the first electrode.

After the S103, the method further includes:

separating the base substrate from the flexible substrate using a laser lift-off device.

In addition, as shown in FIG. 9, which is a flow chart of another method for manufacturing a flexible display panel according to an embodiment of the present disclosure, the method includes the following processes.

In S10, a glass substrate is provided.

In S20, a back plate is manufactured on the glass substrate.

The back plate includes a flexible substrate, and the flexible substrate has a pixel region and a perforated region and is provided with a pixel unit in the pixel region. Therefore, the S20 includes: manufacturing a flexible substrate on the glass substrate, and manufacturing a thin film encapsulation layer, a planarization layer, a first electrode, and a pixel definition layer in the pixel region of the flexible substrate.

In S30, a through hole is formed in the perforated region of the flexible substrate by etching.

In S40, an organic coating layer is formed by coating the through hole with an organic material.

The organic coating layer extends from the hole wall to a bottom corner proximal to the hole bottom of the through hole, and extends from the bottom corner towards the inside of the through hole.

In S50, an organic light-emitting layer and a second electrode are evaporated above the first electrode.

In S60, encapsulation is performed with a thin film encapsulation layer, wherein the thin film encapsulation layer extends along the hole wall of the through hole to the hole bottom of the through hole and is disposed on a side of the organic coating layer distal from the glass substrate.

In S70, a material between the through hole and the glass substrate is removed by etching.

In S80, the glass substrate is separated from the flexible substrate by a laser lift-off device.

For the flexible display panel manufactured by the above method, the organic coating layer is formed by organically coating the through hole before thin film encapsulation, such that during thin film encapsulation, a contact area between the thin film encapsulation layer and the glass substrate is reduced or the contact between the thin film encapsulation layer and the glass substrate is avoided to reduce the difficulty in separating the glass substrate from the flexible substrate, which makes it easier to separate the flexible substrate from the glass substrate, achieves non-destructive separation, and further ensures the structural integrity of the flexible substrate.

The above method further includes manufacturing a support column on the pixel definition layer, and the support column supports a mask plate for manufacturing an organic light-emitting layer. In a possible embodiment, the support column and the organic coating layer are manufactured in the same layer. In this way, the organic coating layer is manufactured by the existing devices and technologies, without device input and adding of processes, which achieves high feasibility and high production efficiency.

In a possible embodiment, the organic coating layer is manufactured by liquid coating of a resin photoresist.

An embodiment of the present disclosure further provides a display device, including the flexible display panel in the above embodiments, and the display device may be a mobile phone, a folding watch, a folding tablet, and the like.

In a first aspect, an embodiment of the present disclosure provides a flexible display panel including a flexible substrate. The flexible substrate includes a first surface and a second surface opposite to each other, and is provided with a thin film transistor layer, a pixel unit, and a thin film encapsulation layer that are stacked on the first surface.

The flexible substrate is provided with a through hole on a side of the thin film transistor layer and the pixel unit, the through hole penetrates the flexible substrate in a direction from the first surface to the second surface, and the thin film encapsulation layer extends along a hole wall of the through hole.

The flexible display panel further includes an organic coating layer disposed on the hole wall, and the thin film encapsulation layer is disposed on a side surface of the organic coating layer distal from the hole wall.

In the flexible display panel according to the embodiment of the present disclosure, the organic coating layer is provided, and the thin film encapsulation layer is disposed on a side of the organic coating layer distal from the hole wall. As the organic coating layer has a certain thickness, the thin film encapsulation layer is farther away from the hole wall than the thin film encapsulation layer in the related art, thus reducing a contact area of direct contact between the thin film encapsulation layer and a glass substrate at a shielding position, and even avoiding direct contact between the thin film encapsulation layer and the glass substrate. In this way, the difficulty in separating the flexible substrate from the glass substrate can be reduced, which makes it easier to separate the flexible substrate from the glass substrate, achieves non-destructive separation, and further ensures the structural integrity of the flexible substrate.

In a possible embodiment, the organic coating layer coats the hole wall and extends from the hole wall towards the inside of the through hole.

In a possible embodiment, the through hole includes a hole bottom proximal to the second surface, and the hole wall has a bottom angle proximal to the hole bottom; and the organic coating layer extends from the hole wall to the bottom corner and extends from the bottom corner towards the inside of the through hole.

In a possible embodiment, the flexible substrate is provided with a first shielding structure protruding towards the inside of the through hole relative to the hole wall; in the direction from the first surface to the second surface, an end of the organic coating layer distal from the hole wall is aligned with or exceeds the first shielding structure.

In a possible embodiment, the organic coating layer includes a resin-based organic material.

In a possible embodiment, the thin film encapsulation layer includes a first inorganic encapsulation layer, an organic encapsulation layer, and a second inorganic encapsulation layer that are stacked, wherein the first inorganic encapsulation layer and the second inorganic encapsulation layer are disposed at two sides of the organic encapsulation layer and the organic encapsulation layer is hermetically coated with the first inorganic encapsulation layer and the second inorganic encapsulation layer.

In a possible embodiment, the thin film encapsulation layer includes an inorganic encapsulation layer and an organic encapsulation layer that are stacked, wherein an outer side of the pixel unit and the hole wall is hermetically coated with the inorganic encapsulation layer, and a side of the inorganic encapsulation layer distal from the flexible substrate is coated with the organic encapsulation layer.

In a possible embodiment, the flexible substrate includes an organic isolation layer and an inorganic isolation layer that are stacked on the first surface, wherein the organic isolation layer and the inorganic isolation layer surround the through hole and are provided with an isolation groove, an opening direction of the isolation groove being a direction from the second surface to the first surface and the isolation groove extending around a periphery of the through hole.

In a possible embodiment, in a direction opposite to the opening direction, an area of an orthographic projection of the inorganic isolation layer on a bottom of the isolation groove is greater than or equal to an area of an orthographic projection of the organic isolation layer on the bottom of the isolation groove.

In a possible embodiment, the flexible display panel includes a planarization layer and a pixel definition layer that are stacked on the thin film transistor layer, wherein the planarization layer is provided with a first opening, and the pixel definition layer is provided with a second opening; and

the pixel unit includes a first electrode and a second electrode, and an organic light-emitting layer disposed between the first electrode and the second electrode, wherein the first electrode is disposed on the planarization layer, is opposite to the second opening, and is connected to a pixel circuit in the thin film transistor layer through the first opening, and the organic light-emitting layer and the second electrode are disposed at the second opening.

In a possible embodiment, the first electrode is an anode, the second electrode is a cathode, the organic light-emitting layer and the cathode are disconnected at a side wall of the isolation groove, and the thin film encapsulation layer is contiguous in the isolation groove.

In a possible embodiment, the organic isolation layer and the planarization layer or the pixel definition layer are disposed in the same layer and made from the same material.

In a possible embodiment, the pixel definition layer is provided with a support column, wherein the support column and the organic coating layer are disposed in the same layer and made from the same material.

In a possible embodiment, the flexible substrate includes a first organic substrate, a first inorganic substrate, and a second organic substrate that are stacked; and the organic coating layer includes a first sub-coating layer and a second sub-coating layer, wherein the first sub-coating layer covers a part of the hole wall corresponding to the first organic substrate, and the second sub-coating layer covers a part of the hole wall corresponding to the second organic substrate.

In a possible embodiment, the first inorganic substrate is overlapped with the first sub-coating layer and the second sub-coating laver in a direction perpendicular to the flexible substrate.

In a possible embodiment, an inorganic insulation film layer is disposed on a side of the first organic substrate distal from the first inorganic substrate and is provided with a planarization layer, wherein a pixel unit is disposed on the planarization layer, and the inorganic insulation film layer is overlapped with the first sub-coating layer in the direction perpendicular to the flexible substrate.

In a second aspect, an embodiment of the present disclosure provides a method for manufacturing a flexible display panel, including the following processes.

providing a glass substrate;

manufacturing a back plate on the glass substrate, wherein the back plate includes a flexible substrate, the flexible substrate includes a pixel region and a perforated region, and the flexible substrate is provided with a thin film transistor layer, a planarization layer, a first electrode, and a pixel definition layer that are stacked in the pixel region;

forming a through hole in the perforated region of the flexible substrate by etching;

forming an organic coating layer by coating a hole wall of the through hole with an organic material, wherein the organic coating layer extends from the hole wall to a bottom corner proximal to a hole bottom of the through hole and extends from the bottom corner towards the inside of the through hole:

evaporating an organic light-emitting layer and a second electrode above the first electrode:

performing encapsulation with a thin film encapsulation layer, wherein the thin film encapsulation layer extends along the hole wall to the hole bottom and is disposed on a side of the organic coating layer distal from the glass substrate:

removing a material between the through hole and the glass substrate by etching; and

separating the glass substrate from the flexible substrate by a laser lift-off device.

In a possible embodiment, the method further includes manufacturing a support column on the pixel definition layer, wherein the support column supports a mask plate for manufacturing the organic light-emitting layer; and

the support column and the organic coating layer are disposed in the same layer and made from the same material.

In a possible embodiment, the organic coating layer is manufactured by liquid coating of a resin photoresist.

In a third aspect, an embodiment of the present disclosure provides a display device including the flexible display panel described in the embodiments of the first aspect.

The display device including the flexible display panel in the above embodiments has the same technical effect as the flexible display panel, which is not repeated herein.

In the descriptions of the present disclosure, it should be understood that orientation or positional relationships indicated by the terms “center.” “upper,” “lower,” “left,” “right,” “vertical”, “horizontal,” “inside,” “outside,” and the like are orientation or positional relationships shown based on the accompanying drawings, only for the ease in describing the present disclosure and simplification of its descriptions, but not indicating or implying that the specified device or element has to be specifically located, and structured and operated in a specific direction, and therefore, should not be understood as limitations to the present disclosure. Moreover, the terms “first,” “second” and “third” are used for descriptive purposes only, and should not be construed to indicate or imply a relative importance.

In the descriptions of the embodiments of the present disclosure, it should be noted that unless otherwise specified and limited, the terms “mount,” “connected,” and “connected to/with” need to be broadly understood, for example, the connection may be fixed connection, detachable connection, or integrated connection; or may be mechanical connection, or electrical connection; or may be direct connection, or indirect connection via an intermediation or internal communication between two elements. Those of ordinary skill in the art can understand the specific meaning of the above terms under specific conditions.

In addition, the technical features involved in the different implementations of the embodiments of the present disclosure described above can be combined as long as they do not conflict with each other.

Therefore, the technical solutions of the embodiments of the present application have been described with reference to the preferred embodiments shown in the accompanying drawings. However, it is easy for those skilled in the art to understand that the protection scope of the embodiments of the present disclosure is obviously not limited to these specific implementations. Without departing from the principles of the embodiments of the present disclosure, those skilled in the art can make equivalent changes or replacements to the relevant technical features, and the technical solutions after these changes or replacements should fall within the protection scope of the embodiments of the present disclosure.

What is claimed is:

1. A flexible display panel, comprising:
a flexible substrate comprising a first surface and a second surface opposite to each other and a through hole that penetrates the flexible substrate in a direction from the first surface to the second surface;
an organic coating layer disposed on a hole wall of the through hole; and
a thin film transistor layer, a pixel unit, and a thin film encapsulation layer that are stacked on the first surface, wherein orthographic projections of the thin film transistor layer and the pixel unit on the second surface are disposed at a side of an orthographic projection of the through hole on the second surface, and the thin film encapsulation layer extends along a side of the organic coating layer distal from the hole wall.

2. The flexible display panel according to claim 1, wherein the hole wall is coated with the organic coating layer, the through hole comprises a hole bottom proximal to the second surface, and the hole wall comprises a bottom corner disposed at the hole bottom; and
the organic coating layer extends from the hole wall to the bottom corner, and covers a part of the hole bottom from the bottom corner.

3. The flexible display panel according to claim 2, wherein the flexible substrate is provided with a first shielding structure protruding towards an inside of the through hole relative to the hole wall; and
in the direction from the first surface to the second surface, an orthographic projection of a first end of the organic coating layer distal from the first surface on the second surface is disposed at a side, proximal to the center of the hole bottom, of an orthographic projection of a second end of the first shielding structure distal from the hole wall on the second surface.

4. The flexible display panel according to claim 2, wherein the flexible substrate is provided with a first shielding structure protruding towards an inside of the through hole relative to the hole wall; and
in the direction from the first surface to the second surface, an orthographic projection of a first end of the organic coating layer distal from the first surface on the second surface is overlapped with an orthographic projection of a second end of the first shielding structure distal from the hole wall on the second surface.

5. The flexible display panel according to claim 1, wherein the organic coating layer comprises a resin-based organic material.

6. The flexible display panel according to claim 1, wherein the thin film encapsulation layer comprises a first inorganic encapsulation layer, an organic encapsulation layer, and a second inorganic encapsulation layer that are stacked, wherein the first inorganic encapsulation layer and the second inorganic encapsulation layer are disposed at two sides of the organic encapsulation layer and the organic encapsulation layer is hermetically coated with the first inorganic encapsulation layer and the second inorganic encapsulation layer.

7. The flexible display panel according to claim 1, wherein the thin film encapsulation layer comprises an inorganic encapsulation layer and an organic encapsulation layer that are stacked, wherein an outer side of the pixel unit and the hole wall is hermetically coated with the inorganic encapsulation layer, and a side of the inorganic encapsulation layer distal from the flexible substrate is coated with the organic encapsulation layer.

8. The flexible display panel according to claim 1, wherein the flexible substrate comprises an organic isolation layer and an inorganic isolation layer that are stacked on the first surface, wherein the organic isolation layer and the inorganic isolation layer surround the through hole and are provided with an isolation groove, an opening direction of the isolation groove being a direction from the second surface to the first surface and the isolation groove extending around a periphery of the through hole.

9. The flexible display panel according to claim 8, wherein in a direction opposite to the opening direction, an area of an orthographic projection of the inorganic isolation layer on a bottom of the isolation groove is greater than or equal to an area of an orthographic projection of the organic isolation layer on the bottom of the isolation groove.

10. The flexible display panel according to claim 8, comprising a planarization layer and a pixel definition layer that are stacked on the thin film transistor layer, wherein the planarization layer is provided with a first opening, and the pixel definition layer is provided with a second opening;
the pixel unit comprises a first electrode and a second electrode, and an organic light-emitting layer disposed between the first electrode and the second electrode, wherein the first electrode is disposed on the planarization layer, is opposite to the second opening, and is connected to the thin film transistor layer through the first opening; and
the organic light-emitting layer and the second electrode are disposed at the second opening.

11. The flexible display panel according to claim 10, wherein the first electrode is an anode, the second electrode is a cathode, the organic light-emitting layer and the cathode are disconnected at a side wall of the isolation groove, and the thin film encapsulation layer is contiguous in the isolation groove.

12. The flexible display panel according to claim 10, wherein the organic isolation layer and the planarization layer or the pixel definition layer are film layers disposed in a same layer and made from a same material.

13. The flexible display panel according to claim 10, wherein the pixel definition layer is provided with a support column.

14. The flexible display panel according to claim 1, wherein the flexible substrate comprises a first organic substrate, a first inorganic substrate, and a second organic substrate that are stacked; and
the organic coating layer comprises a first sub-coating layer and a second sub-coating layer, wherein the first sub-coating layer covers a part of the hole wall corresponding to the first organic substrate, and the second sub-coating layer covers a part of the hole wall corresponding to the second organic substrate.

15. The flexible display panel of claim 14, wherein an orthographic projection of the first inorganic substrate on the second surface is overlapped with an orthographic projection of the first sub-coating layer on the second surface and an orthographic projection of the second sub-coating layer on the second surface.

16. The flexible display panel according to claim 14, further comprising an inorganic insulation film layer and a planarization layer that are stacked on a side of the first organic substrate distal from the first inorganic substrate, wherein the pixel unit is disposed on the planarization layer; and
an orthogonal projection of the inorganic insulation film layer on the second surface is overlapped with an orthogonal projection of the first sub-coating layer on the second surface.

17. A method for manufacturing a flexible display panel, comprising:
providing a flexible substrate, wherein the flexible substrate comprises a first surface and a second surface opposite to each other and a through hole that penetrates the flexible substrate in a direction from the first surface to the second surface;
forming an organic coating layer on the flexible substrate, wherein the organic coating layer is formed on a hole wall of the through hole; and
forming, on the first surface, a thin film transistor layer, a pixel unit, and a thin film encapsulation layer that are stacked, wherein orthographic projections of the thin film transistor layer and the pixel unit on the second surface are disposed at a side of an orthographic projection of the through hole on the second surface, and the thin film encapsulation layer extends along a side of the organic coating layer distal from the hole wall.

18. The method according to claim 17, wherein providing the flexible substrate comprises:
forming a flexible back plate on a base substrate, wherein the flexible back plate comprises a perforated region and a pixel region, and a thin film transistor layer, a planarization layer, a first electrode, and a pixel definition layer are stacked in the pixel region;
forming the through hole in the perforated region of the flexible back plate by etching, to process the flexible back plate into the flexible substrate;
forming the organic coating layer on the flexible substrate comprises:
forming a support column and the organic coating layer on the pixel definition layer, wherein the support column is configured to support a mask plate for manufacturing an organic light-emitting layer;
evaporating the organic light-emitting layer and a second electrode above the first electrode; and
upon forming, on the first surface, the thin film transistor layer, the pixel unit, and the thin film encapsulation layer that are stacked, the method further comprises:
separating the base substrate from the flexible substrate using a laser lift-off device.

19. The method according to claim 17, wherein the organic coating layer is manufactured by liquid coating of a resin photoresist.

20. A display device, comprising a flexible display panel, wherein the flexible display panel comprises:
a flexible substrate comprising a first surface and a second surface opposite to each other and a through hole that penetrates the flexible substrate in a direction from the first surface to the second surface;
an organic coating layer disposed on a hole wall of the through hole; and
a thin film transistor layer, a pixel unit, and a thin film encapsulation layer that are stacked on the first surface, wherein orthographic projections of the thin film transistor layer and the pixel unit on the second surface are disposed at a side of an orthographic projection of the through hole on the second surface, and the thin film encapsulation layer extends along a side of the organic coating layer distal from the hole wall.
